(19) United States
(12) Patent Application Publication
(10) Pub. No.: US 2026/0139902 A1
(43) Pub. Date: May 21, 2026

(54) Heating element for a substrate processing system

(71) Applicant: Black Semiconductor Netherlands B.V., Zoetermeer (NL)

(72) Inventors: Dominique Joseph Wehenkel, Zoetemeer (NL); Richard Van Rijn, Zoetemeer (NL)

(73) Assignee: Black Semiconductor Netherlands B.V., Zoetermeer (NL)

(21) Appl. No.: 19/120,232

(22) PCT Filed: Oct. 20, 2023
(86) PCT No.: PCT/NL2023/050554

§ 371 Date: Apr. 11, 2025

(30) Foreign Application Priority Data
Oct. 21, 2022 (NL) 2033372

(51) Int. Cl. F27B 17/00; F27D 11/02; F27D 99/00; H05B 3/14; H10P 72/00

(52) U.S. Cl. CPC F27B 17/0025; F27D 11/02; H05B 3/145; F27D 2099/0008; H05B 2203/007; H05B 2203/037; H10P 72/0436

(57) ABSTRACT

The invention relates to a heating element, a substrate processing system comprising such a heating element, and a method for processing a substrate in such a substrate processing system. The heating element comprises an electrically conductive electrode, wherein the electrically conductive electrode extends along a path between an input contact and an output contact. The electrically conductive electrode comprises a segment along the path in which the electrically conductive electrode is split in at least two separate electrically conductive electrode branches which are electrically connected in parallel. The electrically conductive electrode and the at least two separate electrically conductive branches comprises a heating component which is configured for generating heat and/or emitting heat radiation when a current is running through the heating component.

### BACKGROUND

The invention relates to a heating element, a substrate processing system comprising such a heating element, and a method for processing a substrate using such a substrate processing system. In particular, the invention relates to a heating element comprising an electrically conductive electrode which extends between an input contact and an output contact, wherein the electrically conductive electrode extends along a path for providing a circuit pattern, wherein the electrically conductive electrode comprise a heating component, and wherein the path is configured to provide an optimized heating performance.

The pattern design of an electrically conductive electrode and/or the arrangement the heating component(s) of a heating element directly affects the performance of the heating element, and most importantly the temperature uniformity over the area of the heating element. A poor uniformity of the heat generated by the heating element in a substrate processing system results in significant unevenness in heating of the substrate, and thus failing to heat the substrate uniformly.

For example, US 2008/0029195 A1 discloses a wafer processing apparatus having an optimized electrode pattern for a resistive heating element. The optimized electrode pattern is designed to compensate for the heat loss around contact areas, electrical connections, and through-holes, etc., by generating more heat near or around those areas, and thereby to provide a maximum temperature uniformity. In addition, US 2008/0029195 A1 teaches to use a multi-zone heater pattern with different geometries and specifications for each zone for obtaining a uniform heater temperature distribution.

Alternatively, US 2021/0398829 A1 discloses a substrate support for a substrate processing system configured to perform a deposition process on a substrate. The substrate support includes a pedestal having an upper surface configure to support a substrate and multiple heating layers vertically stacked within the pedestal below the upper surface. Each of the multiple heating layers includes a respective resistive heating element in the form of a resistive coil. In at least one of the heating layers, the pitch of the resistive coil in a radial zone of the substrate support is different from the pitch of the resistive coil in an other radial zone of the substrate support. Accordingly the watt density of the resistive heating element of the at least one heating layer varies in the radial zone relative to the other radial zones of the substrate support. By arranging different coils with different geometries in the various heating layers and/or by individual controlling the power provided to the various heating layers, a non-uniformity in the temperature distribution on the upper surface of the pedestal can be reduced.

Both prior art references above recognize the problem of heat loss at the peripheral edge of the heater. According to US 2008/0029195 A1 this heat loss can be compensated by using an outermost electrode path that is narrower for more local heat generation. According to US 2021/0398829 A1 this heat loss can be compensated by using more closely packed coil of the heating element in the outer zone to increase the heat generation in the outer zone.

### SUMMARY OF THE INVENTION

It is an object of the present invention to provide a heating element with an alternative way to vary the heat output in different regions of the heating element.

According to a first aspect, the present invention pertains to a heating element for a substrate processing system, wherein the heating element comprises an electrically conductive electrode, wherein the electrically conductive electrode extends along a path between an input contact and an output contact, wherein the electrically conductive electrode comprises a segment along the path in which the electrically conductive electrode is split in at least two separate electrically conductive electrode branches which are electrically connected in parallel, and wherein the electrically conductive electrode and the at least two separate electrically conductive branches each comprises a heating component which is configured for generating heat and/or emitting heat radiation when a current is running through the heating component.

In the heating element of the invention, the electrically conductive electrode comprises a segment in which the electrode is split in at least two separate electrically conductive electrode branches which are electrically connected in parallel. Consequently, at the splitting point, the total current through the electrically conductive electrode is divided over the at least two separate electrically conductive electrode branches, dependent on the electrical resistance of the separate electrically conductive electrode branches with respect to each other. For example, if the electrode is split in two separate electrode branches and if the electrical resistance of the two electrode branches is substantially equal, the total current through the electrically conductive electrode is divided such that the current through each of the two electrode branches is substantially ½ of the total current. Since the power generated by a heating element is a function of the current through the heating element, the power generated by the heating element arranged in the electrically conductive electrode before the split is higher than the power generated by the heating elements arranged in each of the separate conductive electrode branches after the split.

Accordingly, in the heating element of the current invention, the power generated in different parts of the electrically conductive electrode is varied by dividing the current through the electrically conductive electrode over at least two separate electrically conductive electrode branches which are electrically connected in parallel. The different parts in particular relate to the parts of the electrically conductive electrode outside the segment on the one hand, and the parts inside the segment where the electrically conductive electrode is split in the at least two separate electrically conductive electrode branches which are electrically connected in parallel. Since the power generated is a function of the current through the electrically conductive electrode, the variation in the generated power can be much larger than for example using only a variation in the resistance of the heating element as described in US 2008/0029195 A1 or a more closely packed heating coil as described in US 2021/0398829 A1.

Heating uniformity becomes more difficult to achieve for processing substrates at exceedingly higher temperatures. At higher temperatures, the heat leakage is generally higher and therefor the non-uniformity in temperature is larger. Due to the possibility to provide a larger variation in the generated power in different parts of the electrically conductive electrode, the heating element of the present invention is particularly suitable for substrate processing systems for processing substrates at higher temperatures, for example for growing 2D graphene layers on a substrate at temperatures in a range between 600-1300 ° C. , in particular at or around 1000° C.

In an embodiment, the heating component extends along the electrically conductive electrode. In an embodiment, the heating component extends along substantially the complete length of the electrically conductive electrode. Accordingly, the heating component is distributed along at least a part of the path, preferably substantially along the complete length of the path of the electrically conductive electrode, which provides a more even distribution of heat generated along the path.

In an embodiment, the heating component comprises an electrically resistive heating component. Since the power generated by an electrically resistive heating component is quadratically related to the current through the resistive heating component, the power generated in the resistive heating component in the electrically conductive electrode before the split can be 4 times as high as the power generated in the resistive heating components in the each of the separate electrically conductive electrode branches after the split (assuming that the electrically conductive electrode is split in two separate electrode branches and that the resistance of each of the separate electrically conductive electrode branches is substantially equal).

In an embodiment, the path is arranged in a plane, preferably in a substantially flat plane. The heating element according to this embodiment is particularly suitable for use in a substrate processing system for processing substantially flat substrates, such as for example thin Silicon wafers or thin sapphire plates.

In an embodiment, the electrically resistive heating component comprises a cross-section area in a direction substantially transverse to a direction along the path from the input contact to the output contact, wherein the cross-section area varies along the path. Since the power generated is inversely proportional to the cross-section area of the electrically resistive heating component, a variation of the cross-section area along the path provides a way of varying the generated heat power along the path of the electrically conductive electrode, which can in particular be used to fine-tune the large variation in the generated power due to the splitting of the electrically conductive electrode in the at least two separate electrically conductive electrode branches which are electrically connected in parallel, in order to optimize the resistive heating element for providing an optimal uniform heating of a substate in a specific application.

In an embodiment, a thickness of the electrically resistive heating component in a direction perpendicular to the plane is substantially constant, and wherein a width of the electrically resistive heating component in a direction parallel to the plane varies along the path. This embodiment provides the same fine-tune possibilities as the previous embodiment and in addition allows to vary the cross-section area in a less elaborate way by only changing the width of the electrically resistive heating component along its path and keeping the thickness of the electrically resistive heating component substantially constant.

In an embodiment, the heating element comprises an edge, preferably a circumferential edge, wherein the electrically conductive electrode comprises a first section adjacent to the edge and a second section, wherein the first and second sections are electrically connected in series, wherein the first section is arranged in between the edge and the second section, wherein the second section of the electrically conductive electrode comprises the segment along the path in which the electrically conductive electrode is split in the at least two separate electrically conductive electrode branches which are electrically connected in parallel. The first section does not comprise a segment in which the electrically conductive electrode is split in the at least two separate electrically conductive electrode branches which are electrically connected in parallel, and accordingly, in use, the total current is running through the electrically conductive electrode of the first section, which thus provides a relatively high power heat generation in the first section in order to compensate for the heat loss at the edge of the plane.

In an embodiment, the first section provides an outer ring which substantially surrounds the second section of the heating element. Accordingly, the compensation for the heat loss at the edge of the heating element is provided substantially along the complete circumference of the heating element. The second section is arranged in an inner zone of the heating element. In the inner zone, the heat loss to the surrounding environment is much less than at the circumferential edge. Accordingly, regulating the uniformity of the heat generation in the inner zone does not need to have such a high power heat generation and the electrically conductive electrode in the inner zone can be split in the at least two separate electrically conductive electrode branches which are electrically connected in parallel. In an embodiment, the temperature profile at the inner zone is fine-tuned using the above described varying of the width of the electrically resistive heating component, in particular the width of electrically resistive heating components in each of the at least two separate electrically conductive electrode branches.

In an embodiment, the electrically conductive electrode comprises two first sections and a second section which are electrically connected in series, wherein the second section is arranged in between the two first sections, wherein each of the two first sections are arranged adjacent to opposite edges, wherein the opposite edges are arranged at a side of the first sections which faces away from the second section. In an embodiment where the heating element has a circular shape, the two first sections each provide a part of an outer ring which substantially surrounds the second section of the heating element. Preferably, the heating element comprises the following items connected in series one behind the other: the input contact, a first section providing a part of the outer ring, a second section arranged in the area inside the outer ring and comprising the at least two separate electrically conductive electrode branches, a first section providing a remaining part of the outer ring, and the output contact. This embodiment provides the same advantages as the previous embodiment, and in addition allows to arrange the input contact and the output contact at or near the circumferential edge for easy connection of the heating element to a power source.

In an embodiment, the second section is substantially completely split in the at least two separate electrically conductive electrode branches which are electrically connected in parallel. Accordingly, the current in the electrically conductive electrode is split after the outer ring, which allows to convert most of the electrical power provided to the heating element to generate heat and/or to emit heat radiation at the outer ring of the heating element, where the larges heat loss occurs, to provide a more uniform heating.

It is noted that the at least two separate electrically conductive electrode branches are recombined again inside the second section. Preferably, the at least two separate electrically conductive electrode branches are confined within the second section.

In an embodiment, the electrically conductive electrode comprises a carbon-based material, preferably a Carbon-Carbon Composite (CCC) material. Such an CCC material allows to use the heating element in substrate processing systems for processing substrates at higher temperatures, for example for growing 2D graphene layers on a substrate at temperatures in a range of 600-1300° C., more preferably at or around 1000° C.

In an embodiment, the heating element is a single zone heating element containing only one input contact and only one output contact. Such a single zone heating element is relatively easy to produce and does not require complex controllers for individually controlling the power for multiple zones as in US 2008/0029195 A1 or multiple vertically stacked coils as in US 2021/0398829 A1.

According to a second aspect, the present invention pertains to a substrate processing system comprising a first and a second heating element according to the heating element or an embodiment thereof as described above, wherein the first and second heating element are arranged in a processing chamber, and wherein the first and second heating elements are spaced apart for arranging a processing compartment between the first and second heating elements. Providing the processing compartment in between two heating elements allows to obtain a more uniform temperature distribution in a surface between the first and second heating elements, while potentially having a temperature gradient in a direction perpendicular to the surface.

In an embodiment, the processing compartment comprises a top wall and a bottom wall, wherein the first and second heating elements are respectively arranged against a surface of the top wall and bottom wall outside the processing compartment. Accordingly the first and second heating elements are arranged outside the processing compartment, and are not or to a lesser extend subjected to materials used inside the processing compartment for processing the substrate, such as, for example, gaseous materials for Chemical Vapor Deposition and/or Plasmas. It is noted that the first and second heating elements and the processing compartment are arranged inside the processing chamber.

In an embodiment, the top wall and the bottom wall of the processing compartment comprises plate of Shapal (AIN). Shapal or Aluminium Nitride is an electrical insulator material with a high thermal conductivity, that can advantageously transmit the heat generated by the heating element to the inside of the processing compartment.

In an embodiment, the bottom wall of the processing compartment is configured for supporting a substrate to be processed. In other words, the wall on top of the lower one of the first and second heating elements is configured for supporting a substrate to be processed. Accordingly, gravity can assist in maintaining the substrate at the desired location inside the processing compartment.

In an embodiment, the substrate processing system further comprises a first heat shield and/or a second heat shield, wherein the first heat shield is arranged spaced apart from the first heating element and at a side of the first heating element which faces away from the processing compartment, wherein the second heat shield is arranged spaced apart from the second heating element and at a side of the second heating element which faces away from the processing compartment. In an embodiment, the first and/or second heat shield comprises a sheet of one or more of acarbon carbon composite (CCC), tungsten, molybdenum, stainless steel. The first and/or second heat shield substantially reduces a heat loss at a side of the heating element facing away from the processing compartment, and as such also contribute to a more uniform heat generation by the heating element. In an embodiment, the substrate processing system comprises multiple first heat shields and/or multiple second heat shields, which multiple heat shields are arranged spaced apart one behind the other in a direction away from the heating element. Preferably the multiple heat shields comprises 4 or 5 heat shields.

In an embodiment, the substrate processing system further comprises a third and/or a fourth heat shield, wherein the third heat shield is configured to provide a ring around the first heating element, wherein the third heat shield is arranged spaced apart from the first heating element, wherein the fourth heat shield is configured to provide a ring around the second heating element, wherein the fourth heat shield is arranged spaced apart from the second heating element. In an embodiment, the third and/or fourth heat shield comprises a sheet of one or more of a carbon carbon composite (CCC), tungsten, molybdenum, stainless steel. The third and/or fourth heat shield substantially reduces a heat loss at the circumferential edge of the heating element, and as such also contribute to a more uniform heat generation by the heating element.

According to a third aspect, the present invention pertains to a method for processing a substrate in a substrate processing system or an embodiment thereof as described above, wherein the method comprises at least the steps of:
providing the substrate and arranging the substrate inside the processing compartment;
heating the substrate inside the processing compartment using the first and second heating elements.

In an embodiment, the first and second heating elements are provided with electrical power for generating heat and/or emitting heat radiation in order to heat the substrate and/or the processing compartment to a temperature in a range between 600-1300° C., in particular at or around 1000° C.

The various aspects and features described and shown in the specification can be applied, individually, wherever possible. These individual aspects, in particular the aspects and features described in the attached dependent claims, can be made subject of divisional patent applications.

### BRIEF DESCRIPTION OF THE DRAWINGS

The invention will be elucidated on the basis of an exemplary embodiment shown in the attached drawings, in which:

FIG. 1A is a schematic view of a first example of a heating element according to the invention;

FIG. 1B is a schematic top view of an alternative of the first example of a heating element according to the invention;

FIG. 2 is a top view of a second example of a heating element according to the invention;

FIG. 3 is a partial cross-section view of a first example of a substrate processing system according to the invention;

FIG. 4 schematically shows a temperature profile in the substrate processing system of FIG. 3; and

FIG. 5 is a top view of a third example of a resistive heating element according to the invention.

### DETAILED DESCRIPTION OF THE INVENTION

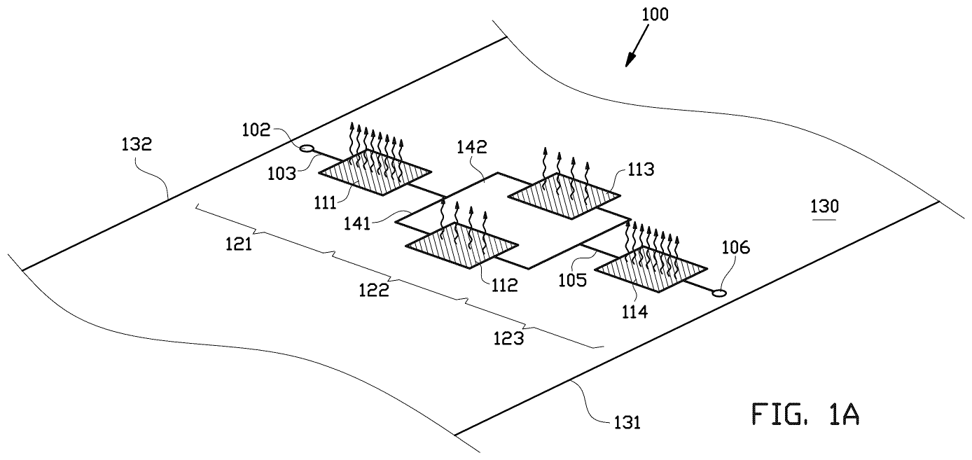

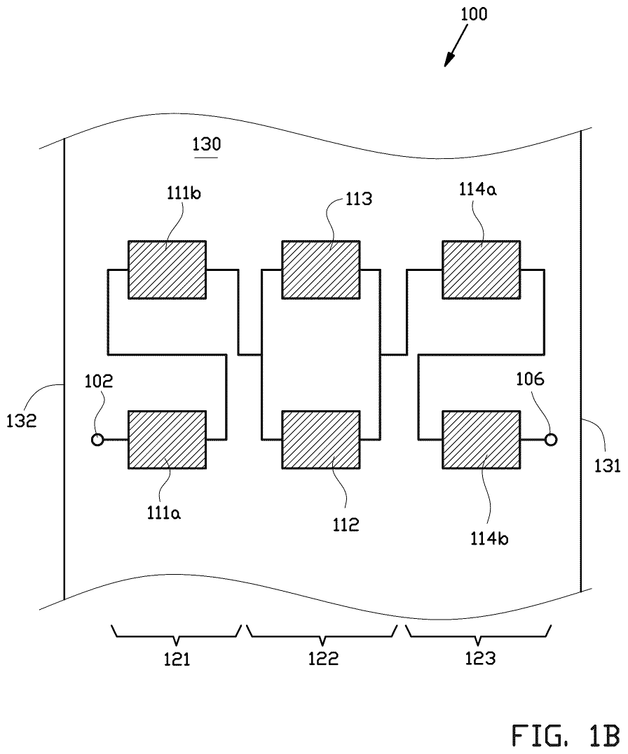

FIG. 1A schematically shows a first example of a heating element 100 according to the invention. The heating element 100 of this example has a substantial planar geometry. It is noted that the plane 130 in which the heating element 100 is arranged does not need to be a flat plane, but may also be curved, for example so that the plane extends substantially parallel to a curved surface of a substrate.

The heating element 100 according to this example comprises the following components electrically coupled in series one behind the other:
an input contact 102,
a first section 121 comprising an electrically conductive electrode 103 which comprises a first heating component 111,
a second section 122 wherein the electrically conductive electrode is split in at least two separate electrically conductive electrode branches 141, 142 which are electrically connected in parallel, wherein each electrically conductive electrode comprises respectively a second heating component 112 and a third heating component 113,
a third section 123 comprising an electrically conductive electrode 105 which comprises a fourth heating component 114, and
an output contact 106.

It is noted that the two separate electrically conductive electrode branches 141, 142 are reconnected in the second section 122.

The first, second, third and/or fourth heating components 111, 112, 113, 114, of this example comprises emitters for emitting infrared or thermal radiation. Preferably the amount of emitted infrared or thermal radiation is a function of the current through the emitters. Examples of an emitter for infrared radiation are heating lamps, infrared lamps or an infrared light-emitting diodes (LED's).

In use of the heating element 100, an electrical current which runs from the input contact 102 to the output contact 106, runs through the electrically conductive electrode 103 of the first section 121, is split in the second section 122 in which the electrical current is divided over the at least two separate electrically conducting electrode branches 141, 142 which are electrically connected in parallel, and is recombined before reaching the third section 123 where again the total electrical current runs through the electrically conductive electrode 105. accordingly, the first heating component 111 and the fourth heating component 114 are subjected to the total current through the heating element 100. The second heating component 112 and the third heating component 113 are subjected to a part of the total current through the heating element 100 dependent on the electrical resistance of the separate electrically conducting electrode branches 141, 142 with respect to each other. In this example there are two separate electrically conducting electrode branches 141, 142 and if the electrical resistance of the two electrode branches 141, 142 is substantially equal, the total current through the heating element 100 is divided such that the current through each of the two electrode branches 141, 142 is substantially ½ of the total current. Since the power generated by a heating components is a function of the current through the heating components, the power generated by the first and fourth heating components 111, 114 is higher than the power generated by the second and third heating components 112, 113 respectively. The relatively high power heat generation in the first section 121 and third section 123 is used to compensate for the heat loss at the edges 131, 132 of the plane 130.

FIG. 1B schematically shows an alternative first example of a heating element 100 according to the invention. The heating element 100 of this example has substantial the same planar geometry as the example in FIG. 1A. In the alternative example of FIG. 1B, the number of heat generating elements along the edges of the heating element is equal to the number of het generating elements in the center of the heating element.

The heating element 100 according to this alternative example comprises the following components electrically coupled in series one behind the other:
an input contact 102,
a first section 121 comprising an electrically conductive electrode 103 which comprises a set of first heating components 111a, 111b, which are electrically connected in series,
a second section 122 wherein the electrically conductive electrode is split in at least two separate electrically conductive electrode branches 141, 142 which are electrically connected in parallel, wherein each electrically conductive electrode comprises respectively a second heating component 112 and a third heating component 113,
a third section 123 comprising an electrically conductive electrode 105 which comprises a set of fourth heating component 114a, 114b, which are electrically connected in series, and
an output contact 106.

It is noted that the two separate electrically conductive electrode branches 141, 142 are reconnected in the second section 122.

Again, the first, second, third and/or fourth heating components 111a, 111b, 112, 113, 114a, 114b, of this alternative example comprises emitters for emitting infrared or thermal radiation, wherein the amount of emitted infrared or thermal radiation is a function of the current through the emitters. Accordingly, heating elements 111a, 111b, 114a and 114b have a high output power because they experience the total current. The Heating elements in the center 112 and 113 are electrically connected in parallel, and thus the total current is divided between these two heating elements and they emit a lower amount of heat. The relatively high power heat generation in the first section 121 and third section 123 is used to compensate for the heat loss at the edges 131, 132 of the plane 130.

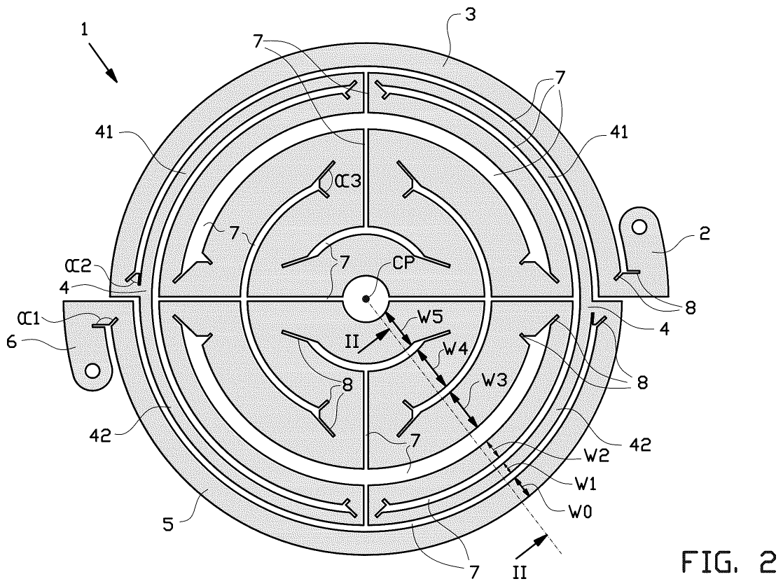

FIG. 2 schematically shows a top view of a first example of a resistive heating element 1 according to the invention. As shown in FIG. 2, the resistive heating element 1 has a substantial circular geometry which is particularly suitable for use in a substrate processing system where the substrates are substantial circular disks, such as, for example, silicon wafers.

The resistive heating element 1 according to this example comprises the following components connected in series one behind the other:
an input contact 2,
an electrically conductive electrode comprising:
   a first section 3 providing a part of the outer ring,
   a second section 4 arranged in the area inside the outer ring wherein the second section 4 is split in two separate electrically conductive electrode branches 41, 42, and
   a third section 5 providing a remaining part of the outer ring,
an output contact 6.

It is noted that the two separate electrically conductive electrode branches 41, 42 are recombined in the second section 4, before the electrically conductive electrode reaches the third section 5. Accordingly, in this example, the two separate electrically conductive electrode branches are confined within the second section 4.

In this example, the third section 5 is substantially symmetric with the first section 3 with respect to the center point CP of the resistive heating element. In addition, the second section 4 is substantially completely split in the two separate electrically conductive electrode branches 41, 42.

Although the thickness of the electrically conductive electrode can vary along the path of the electrically conductive electrode, in this example the resistive heating element 1 has a thickness in a direction perpendicular to the plane of the drawing which is substantially constant. In this example, the resistive heating element 1 is made from a Carbon-Carbon Composite (CCC) material with a thickness of approximately 3 mm. The slots 7 which define the path of the electrically conductive electrode are cut out of a plate of the CCC material using, for example, a water jet cutter.

As schematically shown in FIG. 2, the two separate electrically conductive electrode branches 41, 42 each has a first tortuous path from the outer ring towards the center point CP of the resistive heating element in a first quarter of the circular area of the resistive heating element and subsequently has a second tortuous path from the center towards the outer ring of the resistive heating element in a second quarter, adjacent to the first quarter, of the circular area of the resistive heating element.

As shown in FIG. 2, the turns in the tortuous path of the electrically conductive electrode is provided with incisions 8. The incisions 8 in the turns of the tortuous path are configured to prevent cold spots in the temperature distribution over the resistive heating element.

In the specific example of FIG. 2, one or more of the turns comprises two incisions 8 which extend at an angle α1, α2, α3 with respect to each other. This angle α1, α2, α3 is an angle which is larger than 0 degrees and smaller than 180 degrees. In the example of FIG. 2, the angle α1, α2, α3 between two incisions 8 at a tun is substantially 45, 90 or 135 degrees. In the example of FIG. 2, substantially each turn, except the one closest to the center point CP of the resistive heating element, comprises the two incisions 8.

Furthermore, the width of the two separate electrically conductive electrode branches 41, 42, of the electrically conductive electrode in a direction parallel to the plane varies along the path. The more the path travels to the center point CP of the resistive heating element, the wider the electrically conductive electrodes become, and the less heat is generated with a certain current flowing through the electrically conductive electrode. This allows fine-tuning of the resistive heating for obtaining an optimal uniform heat distribution in a specific application.

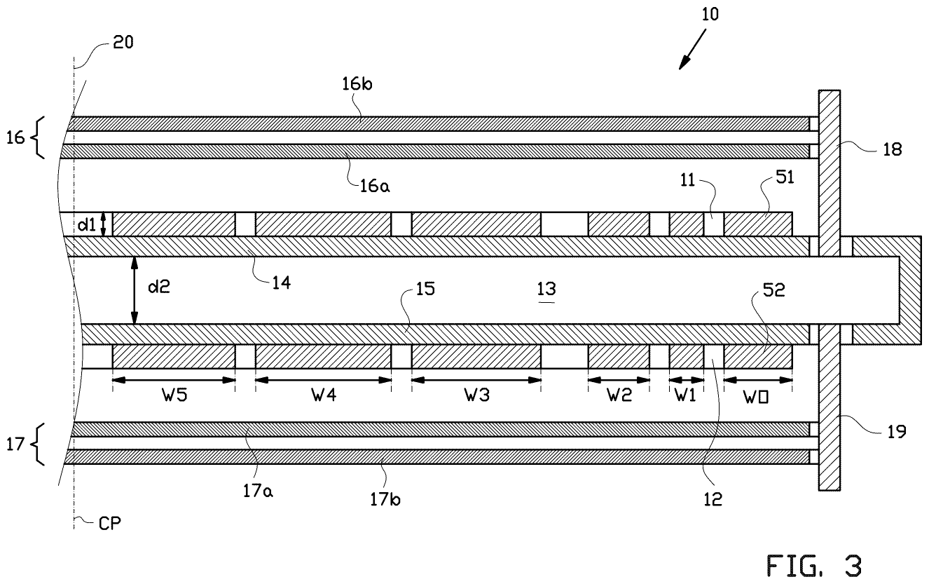

FIG. 3 schematically shows a partial cross-section view of a first example of a substrate processing system 10 according to the invention. The cross-section of FIG. 3 ranges from the center point P to the circumferential edge of the substrate processing system 10. Accordingly, the left hand side of the cross-section is equal to a mirror image in the line 20 through the center point CP.

The substrate processing system 10 comprising a first heating element 11 and a second heating element 12. Each of the first and second heating elements 11, 12 preferably comprise a resistive heating element 1 as shown in FIG. 2. The substrate processing system 10 further comprises a processing compartment 13 which is arranged in between the first and second heating elements 11, 12. The processing compartment 13 comprises a top wall 14 and a bottom wall 15, which are made from a heat conductive material, in this particular example from Shapal (AlN). The bottom wall 15 is configured for supporting a substrate to be processed, such as a silicon wafer. In addition, the processing compartment 13 is configured to allow the introduction of processing gases or vapors into the processing compartment 13. The substrate processing system 10 is arranged inside a processing chamber (not shown).

As schematically shown in FIG. 3, the first heating element 11 is arranged abutting against the side of the top wall 14 facing outside the processing compartment 13, and the second heating element 12 is arranged abutting against the side of the bottom wall 15 facing outside the processing compartment 13.

Furthermore, the substrate processing system 10 comprises a first heat shield 16 which is arranged spaced apart from the first heating element 11 and at a side of the first heating element 11 which faces away from the processing compartment 13. In addition, the substrate processing system 10 comprises a second heat shield 17 which is arranged spaced apart from the second heating element 12 and at a side of the second heating element 12 which faces away from the processing compartment 13. In particular, the first heat shield 16 and the second heat shield 17 comprises two layers 16a, 16b, 17a, 17b of a heat reflecting and/or insulating material. In this example, the first and second heat shield 16, 17 comprises layers 16a, 16b, 17a, 17b comprising a sheet of one or more of a carbon carbon composite (CCC), tungsten, molybdenum, stainless steel

The substrate processing system 10 further comprises a third heat shield 18 which forms a ring around the first heating element 11 and is spaced apart from the first heating element 11. The third heat shield 18 is connected to the top wall 14 of the processing chamber 13 and extends in a direction perpendicular the surface of the top wall 14. In the example of FIG. 3, the first heat shield 16 is connect to the third heat shield 18 at a position spaced apart from the top wall 14 and the first heating element 11.

In addition, the substrate processing system 10 comprises a fourth heat shield 19 which forms a ring around the second heating element 12 and is spaced apart from the second heating element 12. The fourth heat shield 19 is connected to the bottom wall 15 of the processing chamber 13 and extends in a direction perpendicular the surface of the bottom wall 15. In the example of FIG. 3, the second heat shield 17 is connect to the fourth heat shield 19 at a position spaced apart from the bottom wall 15 and the second heating element 12. In this example, the third and fourth heat shield 18, 19 are made from stainless steel or molybdenum.

It is noted that the third and fourth heat shield 18, 19 are connected to or are a part of the processing chamber or housing of the substrate processing system 10, which processing chamber is preferably provided with ducts for a cooling fluid, for example for cooling water. In such substrate processing system 10, this is an additional reason for an increased heat loss at the peripheral edge of the first and second heating elements 11, 12. As described in more detail above, this heat loss is compensated by the outer ring 51, 52 of the first and second heating elements 11, 12. The outer ring 51, 52 has a width w0, through which, in use, the complete driving current is running. Between the outer ring 51, 52 and the center point CP, the path of the electrically conductive electrode is split in two separate electrically conductive electrode branches which are electrically connected in parallel (see FIG. 2), and thus, in use, only a part of the complete driving current is running through the electrically conductive electrode branches. In the example of FIG. 2, the electrically conductive electrode branches have a substantially equal resistance, and accordingly the total current is divided substantially in half when running through one of the electrically conductive electrode branches.

As schematically shown in FIGS. 2 and 3, the width of each of the electrically conductive electrode branches changes as a function from the distance to the center point CP. By selecting an appropriate set of widths w1, w2, w3, w4, w5, the temperature of the first and second resistive heating element 11, 12 can be optimized to provide a substantially uniform temperature distribution.

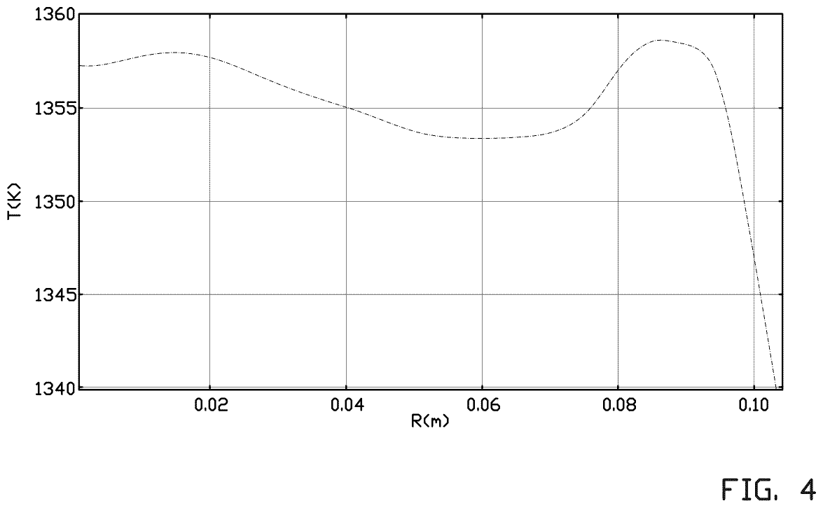

FIG. 4 schematically shows simulation of a temperature profile in the substrate processing system of FIG. 3, where:
the processing compartment 13 has a height of 10 mm;
the top wall 14 and the bottom wall 15 have a thickness of 3 mm and are made of Shapal;
the first and second resistive heating elements 11, 12 have a thickness of 3 mm, have a diameter of 110 mm, and the electrically conductive electrode branches inside the outer ring 51, 52 comprise 5 coils with w1=7 mm, w2=9 mm, w3=19 mm, w4=20 mm and w5=18 mm.

As schematically shown in FIG. 4, it is expected that the temperature variation over the heating elements 11, 12 is about 6 degrees around a working temperature of about 1355 degrees, which is a variation of about 0,4 %. It is noted that R(m) in the graph of FIG. 4 is the distance from the centre point CP.

The trough in the temperature profile may even be decreased by changing the width w3. In addition or alternatively, each of the electrically conductive electrode branches may be split again in two electrically conductive electrode sub-branches which are electrically connected in parallel, which would divide the current that in use is running through an electrically conductive electrode branch again over the two electrically conductive electrode sub-branches.

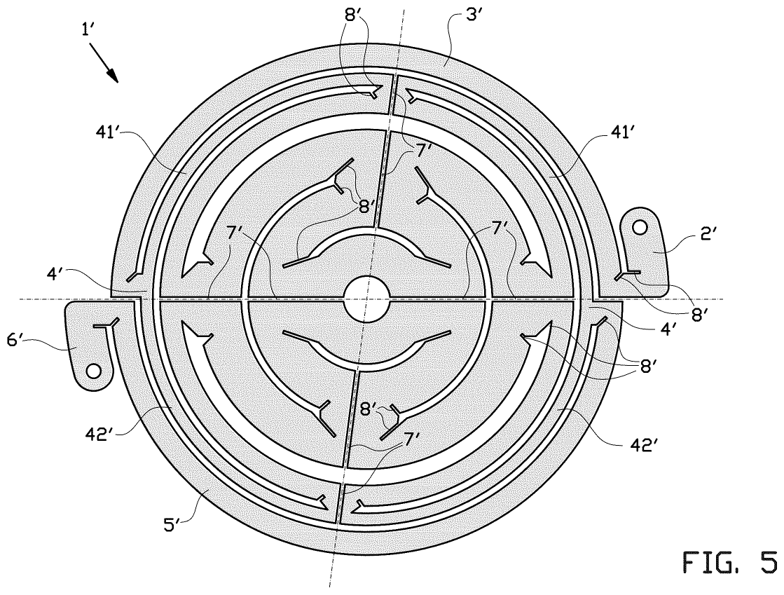

FIG. 5 is a top view of a second example of a resistive heating element 1′ according to the invention, in which several small changes have been made. The most predominant when compared to the first example of FIG. 2 is, that the first tortuous path from the outer ring 3′ towards the center point CP of the resistive heating element covers an area which is larger than a quarter of the circular area of the resistive heating element 1′ and subsequently has a second tortuous path from the center towards the outer ring 3′ of the resistive heating element covers an area which is smaller than a quarter of the circular area of the resistive heating element 1′. As a consequence, the radial arranged slots 7′ are no longer substantially perpendicular to each other, as they are in the first example of FIG. 2, which allows to adjust the resistive heating element 1′ to the specific requirements and features of a substrate processing system, such as, for example, the positions where gases or vapors for processing substrates are arranged in the substrate processing system and/or the position of the opening for introducing the substrate in the processing compartment or for removing the substrate out of the processing compartment, and of course to further uniform the temperature distribution over the area of the resistive heating element.

In addition, some of the slits 8′ are shaped differently to optimize preventing cold spots in the temperature distribution over the resistive heating element 1′.

It is to be understood that the above description is included to illustrate the operation of the preferred embodiments and is not meant to limit the scope of the invention. From the above discussion, many variations will be apparent to one skilled in the art that would yet be encompassed by the scope of the present invention.

In summary, the present invention relates to a heating element, a substrate processing system comprising such a heating element, and a method for processing a substrate in such a substrate processing system. The heating element comprises an electrically conductive electrode, wherein the electrically conductive electrode extends along a path between an input contact and an output contact. The electrically conductive electrode comprises a segment along the path in which the electrically conductive electrode is split in at least two separate electrically conductive electrode branches which are electrically connected in parallel. The electrically conductive electrode and the at least two separate electrically conductive branches comprises a heating component which is configured for generating heat and/or emitting heat radiation when a current is running through the heating component.

1. A heating element for a substrate processing system, wherein the heating element comprises an electrically conductive electrode, wherein the electrically conductive electrode extends along a path between an input contact and an output contact,
wherein the electrically conductive electrode comprises a segment along the path in which the electrically conductive electrode is split in at least two separate electrically conductive electrode branches which are electrically connected in parallel, and
wherein the electrically conductive electrode and the at least two separate electrically conductive branches each comprises a heating component which is configured for generating heat and/or emitting heat radiation when a current is running through the heating component.

2. The heating element according to claim 1, wherein the heating component extends along the electrically conductive electrode.

3. The heating element according to claim 1, wherein the heating component comprises an electrically resistive heating component.

4. The heating element according to claim 3, wherein in a direction substantially transverse to a direction along the path from the input contact to the output contact, the electrically resistive heating component comprises a cross-section area, wherein the cross-section area varies along the path.

5. The heating element according to claim 4, wherein the path is arranged in a plane, wherein a thickness of the electrically resistive heating component in a direction perpendicular to the plane is substantially constant, and wherein a width of the electrically resistive heating component in a direction parallel to the plane varies along the path.

6. The heating element according to claim 1, wherein the heating element comprises an edge, wherein the electrically conductive electrode comprises a first section adjacent to the edge and a second section, wherein the first and second sections are electrically connected in series, wherein the first section is arranged between the edge and the second section, wherein the second section of the electrically conductive electrode comprises the segment along the path in which the electrically conductive electrode is split in the at least two separate electrically conductive electrode branches which are electrically connected in parallel.

7. The heating element according to claim 6, wherein the first section provides an outer ring which substantially surrounds the second section of the heating element, or wherein the electrically conductive electrode comprises two first sections and a second section which are electrically connected in series, wherein the second section is arranged in between the two first sections, wherein each of the two first sections provides a part of an outer ring which substantially surrounds the second section of the heating element.

8. The heating element according to claim 6, wherein the second section is substantially completely split in the at least two separate electrically conductive electrode branches which are electrically connected in parallel.

9. The heating element according to claim 1, wherein the electrically conductive electrode comprises a carbon-based material, preferably a Carbon-Carbon Composite (CCC) material.

10. The heating element according to claim 1, wherein the heating element is a single zone heating element containing only one input contact and only one output contact.

11. A substrate processing system comprising a first and a second heating element according to the heating element of claim 1, wherein the first and second heating element are arranged in a processing chamber, and wherein the first and second heating element are spaced apart for arranging a processing compartment between the first and second heating elements.

12. The substrate processing system according to claim 11, wherein the processing compartment comprises a top wall and a bottom wall, wherein the first and second heating elements are respectively arranged against a surface of the top wall and bottom wall outside the processing compartment, preferably wherein the top wall and the bottom wall comprises a plate of Shapal (AlN).

13. The substrate processing system according to claim 12, wherein the bottom wall of the processing compartment is configured for supporting a substrate to be processed.

14. The substrate processing system according to claim 11, wherein the substrate processing system further comprises a first heat shield and/or a second heat shield,
wherein the first heat shield is arranged spaced apart from the first heating element and at a side of the first heating element which faces away from the processing compartment,
wherein the second heat shield is arranged spaced apart from the second heating element and at a side of the second heating element which faces away from the processing compartment.

15. The substrate processing system according to claim 11, wherein the substrate processing system further comprises a third and/or a fourth heat shield,
wherein the third heat shield is configured to provide a ring around the first heating element, wherein the third heat shield is arranged spaced apart from the first heating element,
wherein the fourth heat shield is configured to provide a ring around the second heating element, wherein the fourth heat shield is arranged spaced apart from the second heating element.

16. A method for processing a substrate in a substrate processing system according to claim 11, wherein the method comprises at least the steps of:
providing the substrate and arranging the substrate inside the processing compartment;
heating the substrate inside the processing compartment using the first and second heating elements.

17. The heating element according to claim 2, wherein the heating component extends along substantially the complete length of the electrically conductive electrode.

18. The substrate processing system according to claim 14, wherein the first and/or second heat shield comprises a sheet of one or more of a carbon carbon composite (CCC), tungsten, molybdenum, stainless steel.

19. The substrate processing system according to claim 14, wherein the first and/or second heat shield comprises a sheet of one or more of a carbon carbon composite (CCC), tungsten, molybdenum, stainless steel
